(19) United States
(12) Patent Application Publication
(10) Pub. No.: US 2025/0315118 A1
(43) Pub. Date: Oct. 9, 2025

(54) TOUCH PANEL AND DISPLAY APPARATUS

(71) Applicants: Wuhan Tianma Microelectronics Co., Ltd., Wuhan (CN); Wuhan Tianma Microelectronics Co., Ltd. Shanghai Branch, Shanghai (CN)

(72) Inventors: Qibing WEI, Wuhan (CN); Peng ZHANG, Wuhan (CN); Yuantao WU, Wuhan (CN)

(21) Appl. No.: 19/242,997

(22) Filed: Jun. 19, 2025

(30) Foreign Application Priority Data
Dec. 24, 2024 (CN) 202411919117.X

(51) Int. Cl. G06F 3/041; H10K 59/40

(52) U.S. Cl. CPC G06F 3/0412; G06F 2203/04107; H10K 59/40

(57) ABSTRACT

Provided are a touch panel and a display apparatus. The touch panel includes a substrate, a touch structure layer, and a first shielding portion. The touch structure layer is provided on one side of the substrate and includes a first electrode portion and a second electrode portion that are provided at intervals along a first direction. The first shielding portion is connected to the first electrode portion, and a distance between the first shielding portion and the substrate is not equal to a distance between the first electrode portion and the substrate. At least a part of an orthographic projection of the first shielding portion on the substrate is located between an orthographic projection of the first electrode portion on the substrate and an orthographic projection of the second electrode portion on the substrate, and the first direction is perpendicular to a thickness direction of the substrate.

### CROSS-REFERENCE TO RELATED APPLICATION

The present disclosure claims priority to Chinese Patent Application No. 202411919117.X, filed on Dec. 24, 2024, the content of which is incorporated herein by reference in its entirety.

### TECHNICAL FIELD

The present disclosure relates to the field of display technologies, and in particular, to a touch panel and a display apparatus.

### BACKGROUND

With the continuous advancement of science and technology, more and more electronic devices are widely used in people's daily life and work, which brings great convenience to people's daily life and work, and have become indispensable and important tools for people today. Touch panels are important components for the electronic devices to achieve human-machine interaction. In traditional touch panels, there is a problem of bright line in a gap between two adjacent touch electrodes, which affects the visual experience.

### SUMMARY

In view of this, it is necessary to provide a touch panel and a display device for alleviating the problem of bright line in a gap between two adjacent touch electrodes.

In a first aspect, an embodiment of the present disclosure provides a touch panel including a substrate, a touch structure layer, and a first shielding portion.

The touch structure layer is provided on one side of the substrate and comprises a first electrode portion and a second electrode portion, and the first electrode portion and the second electrode portion are provided at intervals along a first direction. The first shielding portion is connected to the first electrode portion, and a distance between the first shielding portion and the substrate is not equal to a distance between the first electrode portion and the substrate.

At least a part of an orthographic projection of the first shielding portion on the substrate is located between an orthographic projection of the first electrode portion on the substrate and an orthographic projection of the second electrode portion on the substrate, and the first direction is perpendicular to a thickness direction of the substrate.

In the touch panel provided by the embodiment of the present disclosure, the first shielding portion is provided, so that at least a part of the orthographic projection of the first shielding portion on the substrate is located between the orthographic projection of the first electrode portion on the substrate and the orthographic projection of the second electrode portion on the substrate. As such, the first shielding portion can shield at least a part of a gap between the first electrode and the second electrode. In this way, the amount of the reflected light emitted from the gap is reduced, alleviating the problem of bright line in the gap, and improving the user's visual experience. Furthermore, the distance between the first shielding portion and the substrate is not equal to the distance between the first electrode portion and the substrate, which is equivalent to that the first electrode portion and the first shielding portion are staggered from each other in the thickness direction of the touch panel, reducing the risk of short circuit between the first shielding portion and the second electrode portion.

In a second aspect, based on the same inventive concept, an embodiment of the present disclosure provides a display apparatus including the touch panel in the first aspect.

In the display apparatus provided by the embodiment of the present disclosure, at least a part of the orthographic projection of the first shielding portion on the substrate is located between the orthographic projection of the first electrode portion on the substrate and the orthographic projection of the second electrode portion on the substrate. As such, the first shielding portion can shield at least a part of a gap between the first electrode and the second electrode. In this way, the amount of the reflected light emitted from the gap is reduced, alleviating the problem of bright line in the gap, and improving the user's visual experience. Furthermore, the distance between the first shielding portion and the substrate is not equal to the distance between the first electrode portion and the substrate, which is equivalent to that the first electrode portion and the first shielding portion are staggered from each other in the thickness direction of the touch panel, reducing the risk of short circuit between the first shielding portion and the second electrode portion.

### BRIEF DESCRIPTION OF DRAWINGS

In order to more clearly illustrate the technical solutions in the embodiments or exemplary embodiments of the present disclosure, the drawings required to be used in the description of the embodiments or exemplary embodiments will be briefly introduced below. Apparently, the drawings in the following description are only some embodiments of the present disclosure. For those of ordinary skill in the art, other drawings may also be derived from these figures without creative efforts.

FIG. 1 is a schematic top view of a touch structure layer of a touch panel provided by an embodiment of the present disclosure in a microscopic perspective;

FIG. 2 is a cross-sectional structural schematic diagram of a cross section A-A in

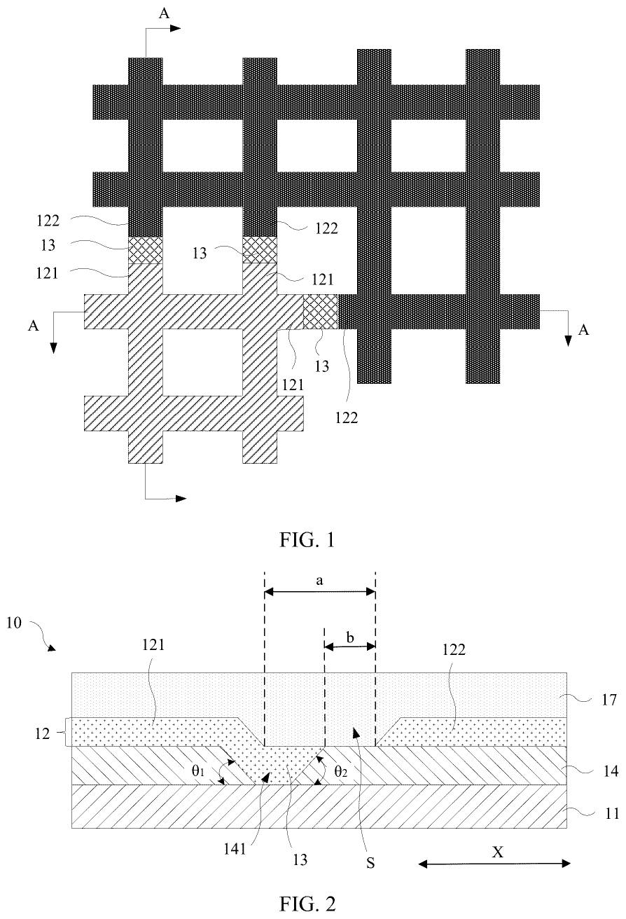

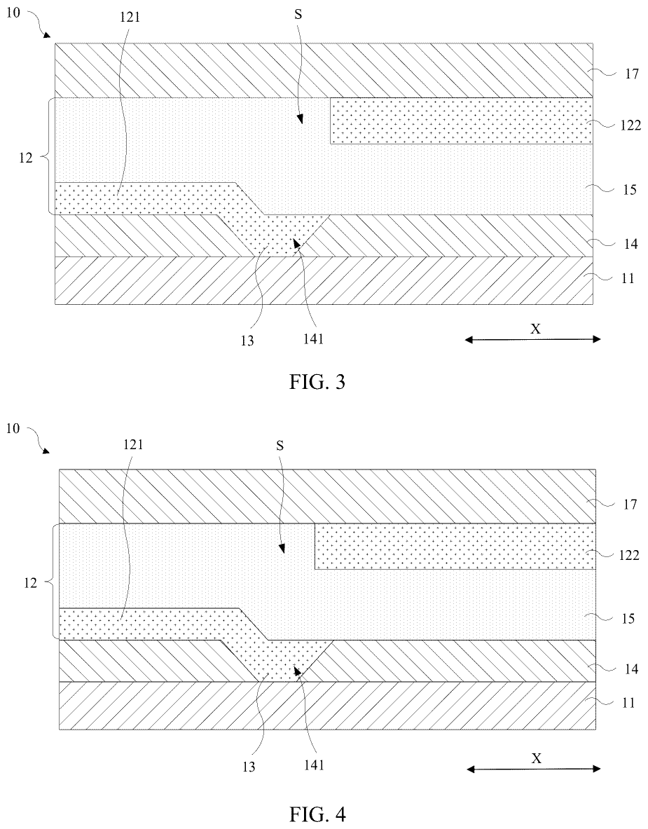

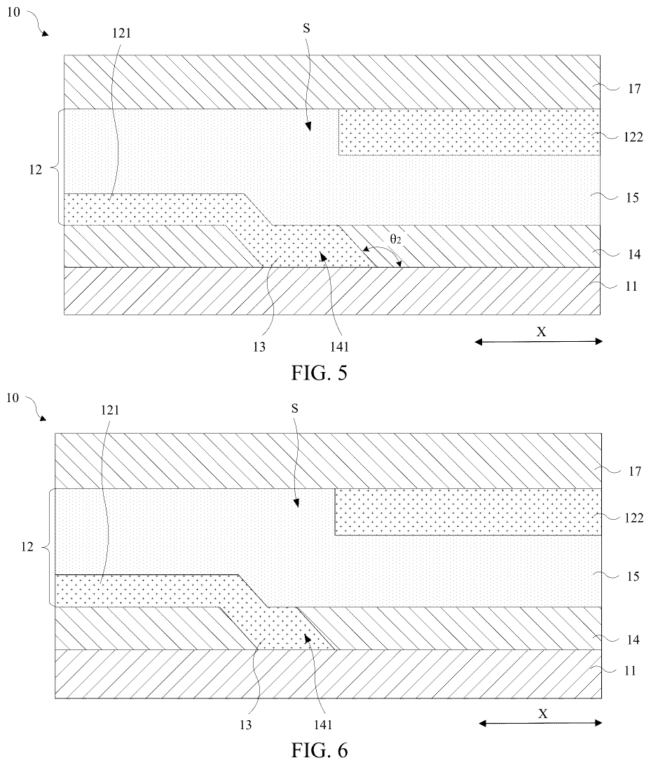

FIG. 1;

FIG. 3 is another cross-sectional structural schematic diagram of the cross section A-A in FIG. 1;

FIG. 4 is a further cross-sectional structural schematic diagram of the cross section A-A in FIG. 1;

FIG. 5 is yet another cross-sectional structural schematic diagram of the cross section A-A in FIG. 1;

FIG. 6 is yet another cross-sectional structural schematic diagram of the cross section A-A in FIG. 1;

FIG. 7 is yet another cross-sectional structural schematic diagram of the cross section A-A in FIG. 1;

FIG. 8 is yet another cross-sectional structural schematic diagram of the cross section A-A in FIG. 1;

FIG. 9 is yet another cross-sectional structural schematic diagram of the cross section A-A in FIG. 1;

FIG. 10 is yet another cross-sectional structural schematic diagram of the cross section A-A in FIG. 1;

FIG. 11 is a partial schematic top view of a touch structure layer of a touch panel provided by an embodiment of the present disclosure;

FIG. 12 is a partial schematic diagram of a cross-sectional structure of a touch panel with a display function provided by an embodiment of the present disclosure; and

FIG. 13 is a structural schematic diagram of a display apparatus provided by an embodiment of the present disclosure.

### REFERENCE SIGNS

1. display apparatus; 10. touch panel; 11. substrate; 12. touch structure layer; 12a. touch driving electrode; 12b. touch sensing electrode; 12c. dummy electrode; 121. first electrode portion; 122. second electrode portion; 13. first shielding portion; 14. first insulating layer; 141. first receiving groove; 15. second insulating layer; 16. second shielding portion; 17. third insulating layer; 171. second receiving groove; 18. optical film layer; 181. groove; 181a. first side wall; 181b. second side wall; 19. driving structure layer; 110. anode metal layer; 111. light-emitting layer; 112. cathode metal layer; s. gap.

### DESCRIPTION OF EMBODIMENTS

To facilitate understanding of the present disclosure, the present disclosure will be described below more comprehensively with reference to the related accompanying drawings. Preferred embodiments of the present disclosure are shown in the drawings. However, the present disclosure may be embodied in many different forms and is not limited to the embodiments described herein. Rather, these embodiments are provided to make the disclosure of the present disclosure more thoroughly and comprehensively be understood.

Unless otherwise defined, all technical and scientific terms used herein have the same meanings as those generally understood by those skilled in the art to which the present disclosure pertains. The terminology used herein in the specification of the present disclosure is for the purpose of describing particular embodiments only and is not intended to limit the present disclosure. The term “and/or” as used herein includes any and all combinations of one or more of the related listed items.

When describing positional relationships, unless otherwise specified, if an element (e.g., a layer, film, or substrate) is referred to as being “on” another element, it may be directly on the other element or there may be an intervening element. Furthermore, when a layer is referred to as being “below” another layer, it may be directly below the other layer or there may be one or more light-emitting units. It also can be understood that when a layer is referred to as being “between” two layers, it may be the sole layer between the two layers or there may be one or more light-emitting units.

In the case of using “including”, “having”, and “comprising” described herein, another component may be added unless a clear limiting term, for example “only”, “consisting of”, etc., is used. Unless otherwise stated, a term in the singular form may include a plural form and cannot be understood as having a number of one.

It should be understood that although the terms “first”, “second”, etc. may be used herein to describe various elements, these elements should not be limited by these terms. These terms are only used to distinguish one element from another element. For example, without departing from the scope of the present disclosure, a first element may be referred to as a second element, and similarly, a second element may be referred to as a first element.

It should also be understood that when explaining an element, although not explicitly described, the element is interpreted as including an error range, which should be within the acceptable deviation range of a specific value determined by a person skilled in the art. For example, “approximately”, “about” or “substantially” can mean within one or more standard deviations, which is not limited herein.

In the specification, the phrase “planar distribution schematic diagram” refers to a figure when a target part is observed from above, and the phrase “cross-sectional schematic diagram” refers to a figure when a cross section taken by vertically cutting a target part is observed from a side.

The drawings are not drawn at a 1:1 scale, and the relative sizes of the elements are drawn only exemplarily and not necessarily to true scale.

In the related technology, touch electrodes of a touch panel are designed with a metal grid, and in order to prevent short-circuiting, a break design is usually used between the touch electrodes for different signals, i.e., a gap is formed between two adjacent touch electrodes. However, under strong light, the reflection from the trace beneath the gap is more serious, resulting in the problem of bright line in the gap, which seriously affects the customer's visual experience.

In view of this, embodiments of the present disclosure provide a touch panel and a display apparatus, in which a first shielding portion is provided, so that at least a part of an orthographic projection of the first shielding portion on a substrate is located between an orthographic projection of a first electrode portion on the substrate and an orthographic projection of a second electrode portion on the substrate. As such, the first shielding portion can shield at least a part of a gap between the first electrode and the second electrode. In this way, the amount of the reflected light emitted from the gap is reduced, alleviating the problem of bright line in the gap, and improving the user's visual experience. Furthermore, a distance between the first shielding portion and the substrate is not equal to a distance between the first electrode portion and the substrate, which is equivalent to that the first electrode portion and the first shielding portion are staggered from each other in a thickness direction of the touch panel, reducing the risk of short circuit between the first shielding portion and the second electrode portion.

In a first aspect, with reference to FIGS. 1 to 12, an embodiment of the present disclosure provides a touch panel 10 including a substrate 11, a touch structure layer 12, and a first shielding portion 13.

The touch structure layer 12 is provided on one side of the substrate 11. The touch structure layer 12 includes a first electrode portion 121 and a second electrode portion 122 that are arranged at intervals along a first direction X. The first direction X is perpendicular to a thickness direction of the substrate 11. The first shielding portion 13 is connected to the first electrode portion 121, and a distance between the first shielding portion 13 and the substrate 11 is not equal to a distance between the first electrode portion 121 and the substrate 11. For example, the distance between the first shielding portion 13 and the substrate 11 is greater than the distance between the first electrode portion 121 and the substrate 11, or the distance between the first shielding portion 13 and the substrate 11 is smaller than the distance between the first electrode portion 121 and the substrate 11.

Further, at least a part of an orthographic projection of the first shielding portion 13 on the substrate 11 is located between an orthographic projection of the first electrode portion 121 on the substrate 11 and an orthographic projection of the second electrode portion 122 on the substrate 11. In other words, in the thickness direction of the touch panel 10, a gap S is formed between the first electrode portion 121 and the second electrode portion 122, and the first shielding portion 13 shields at least a part of the gap S.

It should be noted that the touch panel 10 in the embodiment of the present disclosure can be an external or integrated type. If the touch panel 10 is an external type, the touch panel 10 can be externally mounted on a display screen to form a touch display panel. In this case, the substrate 11 is a base material layer for carrying the touch structure layer 12 and the first shielding portion 13. If the touch panel 10 is an integrated type, the touch panel 10 can be integrated in a display screen to form a touch display panel. In this case, the substrate 11 can be a film layer (for example, an encapsulation layer) in the display screen.

In the touch panel 10 provided by the embodiment of the present disclosure, the first shielding portion 13 is provided so that at least a part of the orthographic projection of the first shielding portion 13 on the substrate 11 is located between the orthographic projection of the first electrode portion 121 on the substrate 11 and the orthographic projection of the second electrode portion 122 on the substrate 11. As such, the first shielding portion 13 can shield the at least a part of the gap S between the first electrode portion and the second electrode portion. In this way, the amount of reflected light emitted from the gap S is reduced, alleviating the problem of bright line in the gap, and improving the user's visual experience.

In addition, the distance between the first shielding portion 13 and the substrate 11 is not equal to the distance between the first electrode portion 121 and the substrate 11, that is, a height of the first shielding portion 13 and a height of the first electrode portion 121 are different from each other. In this way, it is equivalent to staggering the first electrode portion 121 and the first shielding portion 13 from each other in the thickness direction of the touch panel 10, which not only makes full use of the space in the thickness direction of the touch panel 10, but also avoids the short circuit problem caused by the fact that when the first shielding portion 13 and the first electrode portion 121 are located at a same height, the first shielding portion 13 is likely to come into contact with the second electrode portion 122.

In an embodiment, the first shielding portion 13 and the first electrode portion 121 are provided in a same layer. As such, the first shielding portion 13 and the first electrode portion 121 can be manufactured synchronously in a same process, reducing the manufacturing cost.

It can be understood that the first shielding portion 13 and the first electrode portion 121 can also be manufactured separately in different processes, which is not limited by the embodiment of the present disclosure.

In an embodiment, the first shielding portion 13 is formed of a same material as the first electrode portion 121. As such, the reflectivity of the first shielding portion 13 and the first electrode portion 121 can be made the same or close to each other. In this way, the reflective effect of the first shielding portion 13 and the first electrode portion 121 is consistent, which is conducive to improving the user's visual experience.

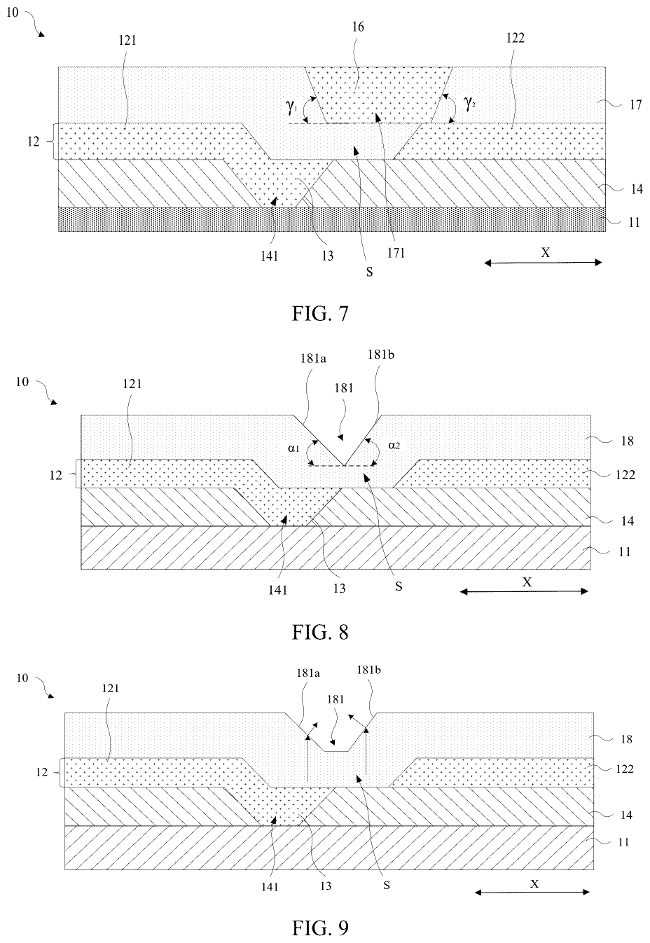

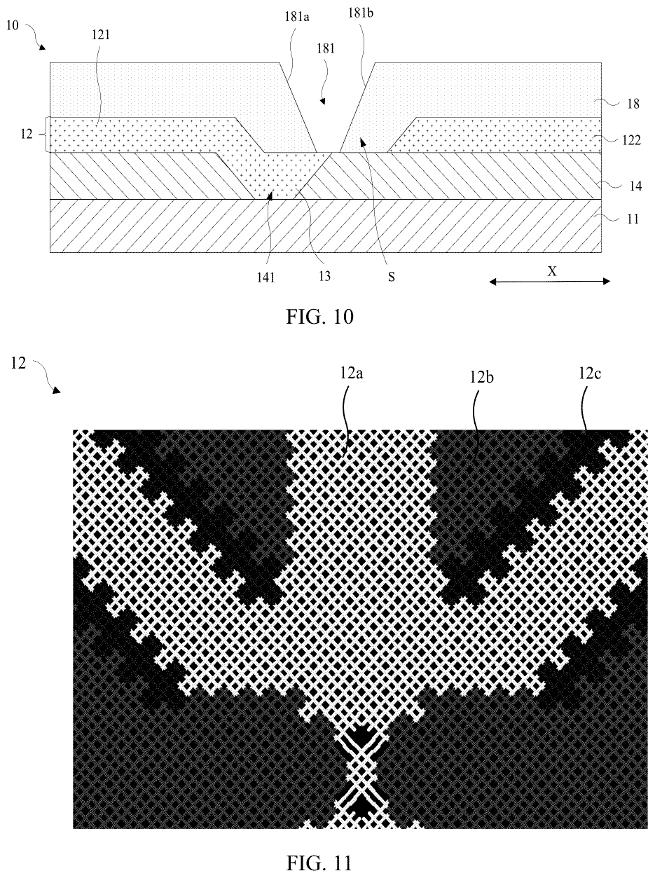

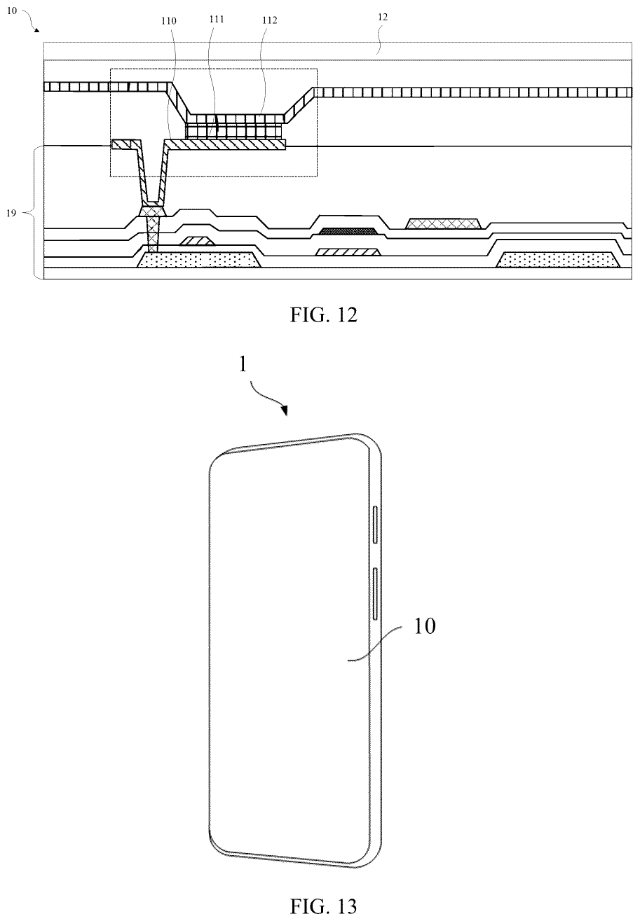

In an embodiment, as shown in FIG. 2, the first shielding portion 13 is located on one side of the first electrode portion 121 close to the substrate 11, and in this case, the distance between the first shielding portion 13 and the substrate 11 is smaller than the distance between the first electrode portion 121 and the substrate 11. The touch panel 10 further includes a first insulating layer 14 located between the first electrode portion 121 and the substrate 11 and also located between the second electrode portion 122 and the substrate 11, the first insulating layer 14 includes a first receiving groove 141, and the first shielding portion 13 is located in the first receiving groove 141.

By providing the first receiving groove 141 in the first insulating layer 14, it is equivalent to providing a receiving space for the first shielding portion 13 in the first insulating layer 14. This avoids the interference between the first shielding portion 13 and other components, which could otherwise have an adverse impact on the arrangement of other components. By providing the first shielding portion 13 on the side of the first electrode portion 121 close to the substrate 11, it facilitates the synchronous manufacturing of the first electrode portion 121 and the first shielding portion 13 in a same process. In an example, the first insulating layer 14 is first formed on the substrate 11, followed by etching the first receiving groove 141 in the first insulating layer 14, and subsequently a first electrode material is deposited and patterned to form the first electrode portion 121 and the first shielding portion 13.

It should be emphasized that the first shielding portion 13 can also be provided on one side of the first electrode portion 121 away from the substrate 11, and the position where the first shielding portion 13 is provided is not specifically limited in the embodiment of the present disclosure.

In an embodiment, as shown in FIG. 2, an included angle between an end surface of the first shielding portion 13 close to an end of the first electrode portion 121 along the first direction X and a plane of the substrate 11 is 01, which is an acute angle. Here, the plane of the substrate 11 is a horizontal plane in FIG. 2, and the end surface of the first shielding portion 13 close to the end of the first electrode portion 121 along the first direction X is a left end surface of the first shielding portion 13 in the figure.

As such, on the one hand, an included angle between a lower surface of the first electrode portion 121 and the left end surface of the first shielding portion 13 can be a non-right angle, and an included angle between a lower surface of the first shielding portion 13 and the left end surface of the first shielding portion 13 can be a non-right angle, thereby reducing the number of right-angle tips in the touch panel 10 and avoiding the occurrence of point discharge phenomenon; and on the other hand, such structure is easier to be formed in the process, reducing the manufacturing difficulty.

In an embodiment, as shown in FIG. 2, an included angle between an end surface of the first shielding portion 13 away from the end of the first electrode portion 121 along the first direction X and the plane of the substrate 11 is 02, which is an acute angle. Here, the plane of the substrate 11 is a horizontal plane in FIG. 2, and the end surface of the first shielding portion 13 away from the end of the first electrode portion 121 along the first direction X is a right end surface of the first shielding portion 13 in the figure.

As such, on the one hand, an included angle between an upper surface of the first shielding portion 13 and the right end surface of the first shielding portion 13 can be a non-right angle, and an included angle between the lower surface of the first shielding portion 13 and the right end surface of the first shielding portion 13 can be a non-right angle, thereby reducing the number of right-angle tips in the touch panel 10 and avoiding the occurrence of point discharge phenomenon; and on the other hand, during fabrication, the first insulating layer 14 is firstly fabricated on the substrate 11, followed by etching the first receiving groove 141 in the first insulating layer 14, and subsequently the first electrode material is deposited and patterned to form the first electrode portion 121 and the first shielding portion 13.

In an embodiment, as shown in FIG. 5, the included angle between the end surface of the first shielding portion 13 away from the end of the first electrode portion 121 along the first direction X and the plane of the substrate 11 is 02, which is an obtuse angle. Here, the plane of the substrate 11 is a horizontal plane in FIG. 5, and the end surface of the first shielding portion 13 away from the end of the first electrode portion 121 along the first direction X is the right end surface of the first shielding portion 13 in the figure.

As such, on the one hand, the included angle between the upper surface of the first shielding portion 13 and the right end surface of the first shielding portion 13 can be a non-right angle, and the included angle between the lower surface of the first shielding portion 13 and the right end surface of the first shielding portion 13 can be a non-right angle, thereby reducing the number of right-angle tips in the touch panel 10 and avoiding the occurrence of point discharge phenomenon; and on the other hand, during fabrication, the first insulating layer 14 at the left side in FIG. 5 is first fabricated on the substrate 11, then the first electrode material is deposited and patterned to form the first electrode portion 121 and the first shielding portion 13, and subsequently the first insulating layer 14 at the right side in FIG. 5 is fabricated on the substrate 11. In this way, the first insulating layer 14 is fabricated through a two-step process.

In an embodiment, as shown in FIG. 2, the distance between the first electrode portion 121 and the substrate 11 is equal to the distance between the second electrode portion 122 and the substrate 11. That is, the first electrode portion 121 and the second electrode portion 122 are located at a same height. It can be understood that in this case, the first electrode portion 121 and the second electrode portion 122 can be provided in a same layer, that is, they are fabricated synchronously in a same process.

Further, the orthographic projection of the first shielding portion 13 on the substrate 11 is spaced apart from the orthographic projection of the second electrode portion 122 on the substrate 11. Specifically, as shown in FIG. 2, a spacing between the first shielding portion 13 and the second electrode portion 122 is b, and a spacing between the first electrode portion 121 and the second electrode portion 122 is a. As such, the first shielding portion 13 can shield most of the gap S without being in contact with the second electrode portion 122, thereby avoiding the occurrence of a short circuit problem.

In an embodiment, as shown in FIG. 3, FIG. 4, FIG. 5, and FIG. 6, the distance between the first electrode portion 121 and the substrate 11 is not equal to the distance between the second electrode portion 122 and the substrate 11. That is, the first electrode portion 121 and the second electrode portion 122 are located at different heights. In other words, the first electrode portion 121 and the second electrode portion 122 are provided in different layers.

Further, the orthographic projection of the first shielding portion 13 on the substrate 11 covers an area between the orthographic projection of the first electrode portion 121 on the substrate 11 and the orthographic projection of the second electrode portion 122 on the substrate 11.

As such, the gap S between the first electrode portion 121 and the second electrode portion 122 can be completely shielded by the first shielding portion 13, thereby maximally alleviating the problem of severe reflection at the gap S.

In an example, as shown in FIG. 3 and FIG. 6, the orthographic projection of the first shielding portion 13 on the substrate 11 contacts the orthographic projection of the second electrode portion 122 on the substrate 11, that is, the orthographic projection of the first shielding portion 13 on the substrate 11 does not overlap with the orthographic projection of the second electrode portion 122 on the substrate 11. As such, the first shielding portion 13 can be fully utilized without causing waste, thereby reducing material cost.

In another example, as shown in FIG. 4 and FIG. 5, the orthographic projection of the first shielding portion 13 on the substrate 11 overlaps with the orthographic projection of the second electrode portion 122 on the substrate 11, that is, a part of the first shielding portion 13 is located directly below the second electrode portion 122. As such, when the second electrode portion 122 is manufactured, even if there are some process errors, the shielding of the gap S by the first shielding portion 13 will not be affected. Therefore, such structure has lower requirements for process accuracy, which is conducive to reducing the process difficulty.

In an embodiment, as shown in FIG. 3, FIG. 4, FIG. 5, and FIG. 6, the touch panel 10 further includes a second insulating layer 15. The second insulating layer 15 is located on the side of the first electrode portion 121 and the side of the first shielding portion 13 away from the substrate 11, and the second insulating layer 15 is located on one side of the second electrode portion 122 close to the substrate 11. That is, the second insulating layer 15 is located between a film layer where the first electrode portion 121 is located and a film layer where the second electrode portion 122 is located. As such, the first electrode portion 121 and the second electrode portion 122 can be prevented from being short-circuited.

In an embodiment, as shown in FIG. 7, the touch panel 10 further includes a second shielding portion 16 connected to the second electrode portion 122, and a distance between the second shielding portion 16 and the substrate 11 is not equal to the distance between the second electrode portion 122 and the substrate 11. For example, the distance between the second shielding portion 16 and the substrate 11 is greater than the distance between the second electrode portion 122 and the substrate 11, or the distance between the second shielding portion 16 and the substrate 11 is smaller than the distance between the second electrode portion 122 and the substrate 11.

At least a part of an orthographic projection of the second shielding portion 16 on the substrate 11 is located between the orthographic projection of the first electrode portion 121 on the substrate 11 and the orthographic projection of the second electrode portion 122 on the substrate 11. In other words, in the thickness direction of the touch panel 10, a gap S is formed between the first electrode portion 121 and the second electrode portion 122, and the second shielding portion 16 shields at least a part of the gap S.

By providing the second shielding portion 16, the gap S can be further shielded, the amount of reflected light emitted from the gap S is further reduced, the problem of bright line in the gap is alleviated, and the user's visual experience is improved. It can also be understood that by providing the second shielding portion 16, on the one hand, a size of the first shielding portion 13 in the first direction X can be reduced; and on the other hand, double-layer shielding is more conducive to solving the problem of poor shielding effect caused by process errors.

In an embodiment, the second shielding portion 16 is provided on one side of the second electrode portion 122 away from the substrate 11. The touch panel 10 further includes a third insulating layer 17. The third insulating layer 17 is located on the side of the first electrode portion 121 and the side of the second electrode portion 122 away from the substrate 11, the third insulating layer 17 includes a second receiving groove 171, and the second shielding portion 16 is provided in the second receiving groove 171.

By providing the second receiving groove 171 in the third insulating layer 17, it is equivalent to providing a receiving space for the second shielding portion 16 in the third insulating layer 17. This avoids the interference between the second shielding portion 16 and other components, which could otherwise have an adverse impact on the arrangement of other components. By providing the second shielding portion 16 on the side of the second electrode portion 122 away from the substrate 11, it is possible to prevent the second shielding portion 16 from contacting the first electrode portion 121 and causing a short circuit. It can be understood that during fabrication, the second receiving groove 171 is first etched in the third insulating layer 17, and then a second shielding material is deposited in the second receiving groove 171 to form the second shielding portion 16.

It can be understood that the second shielding portion 16 can also be provided on the side of the second electrode portion 122 close to the substrate 11, and the position where the second shielding portion 16 is provided is not specifically limited in the embodiment of the present disclosure.

In an embodiment, the first shielding portion 13, the first electrode portion 121, the second shielding portion 16, and the second electrode portion 122 are formed of a same material. As such, the reflectivity of the first shielding portion 13, the first electrode portion 121, the second shielding portion 16, and the second electrode portion 122 can be made the same or close to each other. In this way, the first shielding portion 13, the first electrode portion 121, the second shielding portion 16, and the second electrode portion 122 have a same reflective effect, which is conducive to improving the user's visual experience.

In an embodiment, as shown in FIG. 7, an included angle between an end surface of the second shielding portion 16 close to an end of the second electrode portion 122 along the first direction X and the plane of the substrate 11 is γ₂, which is an acute angle. An included angle between an end surface of the second shielding portion 16 away from the end of the second electrode portion 122 along the first direction X and the plane of the substrate 11 is γ₁, which is an acute angle. Here, the plane of the substrate 11 is a horizontal plane in FIG. 7. The end surface of the second shielding portion 16 close to the end of the second electrode portion 122 along the first direction X is a right end surface of the second shielding portion 16 in the figure, and the end surface of the second shielding portion 16 away from the end of the second electrode portion 122 along the first direction X is a left end surface of the second shielding portion 16 in the figure.

As such, on the one hand, an included angle between an upper surface of the second electrode portion 122 and the right end surface of the second shielding portion 16 can be a non-right angle, an included angle between an upper surface of the second shielding portion 16 and the right end surface of the second shielding portion 16 can be a non-right angle, an included angle between a lower surface of the second shielding portion 16 and the right end surface of the second shielding portion 16 can be a non-right angle, an included angle between the upper surface of the second shielding portion 16 and the left side end surface of the second shielding portion 16 can be a non-right angle, and an included angle between the lower surface of the second shielding portion 16 and the left side end surface of the second shielding portion 16 can be a non-right angle, thereby reducing the number of right-angle tips in the touch panel 10 and avoiding the occurrence of the point discharge phenomenon; and on the other hand, such structure is easier to be formed in the process, reducing the manufacturing difficulty.

In an embodiment, the orthographic projection of the first shielding portion 13 on the substrate 11 overlaps or contacts the orthographic projection of the second shielding portion 16 on the substrate 11. As such, the first shielding portion 13 and the second shielding portion 16 can completely shield the gap S between the first electrode portion 121 and the second electrode portion 122, thereby maximally alleviating the problem of severe reflection at the gap S.

In an embodiment, as shown in FIG. 8, FIG. 9, and FIG. 10, the touch panel 10 further includes an optical film layer 18 located on the side of the first electrode portion 121 and the side of the second electrode portion 122 away from the substrate 11. A gap S is formed between the first electrode portion 121 and the second electrode portion 122, and a groove 181 is included on one side of the optical film layer 18 away from the substrate 11, and the groove 181 and the gap S overlap along the thickness direction of the substrate 11.

As such, by providing the optical film layer 18 and providing the groove 181 overlapping with the gap S on the optical film layer 18, the reflected light passes through the groove 181 when it is emitted from the gap S, as shown in FIG. 9. The groove 181 can change the exiting path of the reflected light, that is, the width of the optical path is further reduced, the width of the bright line under such strong light is weakened, and even is invisible to the naked eye, thereby fundamentally improving the customer's visual experience.

It should be noted that in the embodiment, there is a spacing between the orthographic projection of the first shielding portion 13 on the substrate 11 and the orthographic projection of the second electrode portion 122 on the substrate 11, and the reflected light is emitted between the first shielding portion 13 and the second electrode portion 122, and then passes through the groove 181.

In an embodiment, as shown in FIG. 8, the groove 181 has a first side wall 181a and a second side wall 181b provided opposite to each other along the first direction X, and the first side wall 181a is located on one side of the second side wall 181b close to the first electrode portion 121. An included angle is formed between a plane of the first side wall 181a and the plane of the substrate 11, and an included angle is formed between a plane of the second side wall 181b and the plane of the substrate 11. Specifically, the included angle between the plane of the first side wall 181a and the plane of the substrate 11 is α₁, which is an acute angle, and the included angle between the plane of the second side wall 181b and the plane of the substrate 11 is α₂, which is an acute angle.

The above configuration can more effectively change the exiting path of the reflected light, thereby improving the reflection phenomenon at the gap S.

In an embodiment, the included angle α₁ between the plane of the first side wall 181a and the plane of the substrate 11 satisfies a relationship of: 30°<α₁<90°. Exemplarily, α₁ can be 30°, 50°, 60°, 70°, 80°, 89°, etc. If α₁ is smaller than 30°, the effect of changing the reflection path is weaker. If &1 is greater than 90°, it is equivalent to that the groove 181 is not provided. Therefore, the above configuration can more effectively change the exiting path of the reflected light, thereby improving the reflection phenomenon at the gap S.

In an embodiment, the included angle α₂ between the plane of the second side wall 181b and the plane of the substrate 11 satisfies a relationship of: 30°<α₂<90°. Exemplarily, α₂ can be 30°, 50°, 60°, 70°, 80°, 89°, etc. If α₂ is smaller than 30°, the effect of changing the reflection path is weaker; and if α₂ is greater than 90°, it is equivalent to that the groove 181 is not provided. Therefore, the above configuration can more effectively change the exiting path of the reflected light, thereby improving the reflection phenomenon at the gap S.

In an example, as shown in FIG. 8, a shape of a cross section of the groove 181 along a direction perpendicular to the paper surface is a triangle. In another example, as shown in FIG. 9, a shape of a cross section of the groove 181 along the direction perpendicular to the paper surface is triangular. It can be understood that the shape of the cross section of the groove 181 can also be other shapes, which is not limited in the embodiment of the present disclosure.

In an embodiment, as shown in FIG. 8 and FIG. 9, the groove 181 penetrates a partial structure of the optical film layer 18 along the thickness direction of the substrate 11. As such, damage to the film layers (e.g., the first electrode portion 121 and the first shielding portion 13) underneath the optical film layer 18 can be avoided during the process of etching the groove 181.

It can be understood that, as shown in FIG. 10, the groove 181 can also penetrate the optical film layer 18 along the thickness direction of the substrate 11.

In an embodiment, as shown in FIG. 11, the touch structure layer 12 includes a touch driving electrode 12a, a touch sensing electrode 12b, and a dummy electrode 12c.

In an embodiment, one of the first electrode portion 121 and the second electrode portion 122 is the touch driving electrode 12a, and the other one of the first electrode portion 121 and the second electrode portion 122 is the touch sensing electrode 12b.

In an embodiment, one of the first electrode portion 121 and the second electrode portion 122 is the touch driving electrode 12a, and the other one of the first electrode portion 121 and the second electrode portion 122 is the dummy electrode 12c.

In an embodiment, one of the first electrode portion 121 and the second electrode portion 122 is the touch sensing electrode 12b, and the other one of the first electrode portion 121 and the second electrode portion 122 is the dummy electrode 12c.

It should be noted that in a same touch panel 10, the first shielding portion 13 and/or the second shielding portion 16 can be provided at the gap S between the touch driving electrode 12a and the touch sensing electrode 12b, the first shielding portion 13 and/or the second shielding portion 16 can also be provided at the gap S between the touch driving electrode 12a and the dummy electrode 12c, and the first shielding portion 13 and/or the second shielding portion 16 can also be provided at the gap S between the touch sensing electrode 12b and the dummy electrode 12c.

In an embodiment, as shown in conjunction with FIG. 2, a size of the first shielding portion 13 along a second direction is not smaller than a size of the first electrode portion 121 along the second direction. The second direction is perpendicular to the first direction X and the thickness direction of the substrate 11. In FIG. 2, the second direction is a direction perpendicular to the paper surface.

As such, it is equivalent to making a width of the first shielding portion 13 not smaller than a width of the first electrode portion 121. As such, a shielding area of the first shielding portion 13 can be made larger, which can maximally alleviate the problem of the bright line in the gap.

In an example, the size of the first shielding portion 13 along the second direction is greater than the size of the first electrode portion 121 along the second direction. In another example, the size of the first shielding portion 13 along the second direction is equal to the size of the first electrode portion 121 along the second direction.

In an embodiment, the size of the first shielding portion 13 along the second direction is not smaller than a size of the second electrode portion 122 along the second direction.

As such, it is equivalent to making the width of the first shielding portion 13 not smaller than a width of the second electrode portion 122. As such, a shielding area of the first shielding portion 13 can be made larger, which can maximally alleviate the problem of the bright line in the gap.

In one example, the size of the first shielding portion 13 along the second direction is greater than the size of the second electrode portion 122 along the second direction. In another example, the size of the first shielding portion 13 along the second direction is equal to the size of the second electrode portion 122 along the second direction.

In an embodiment, as shown in FIG. 7, a size of the second shielding portion 16 along the second direction is not smaller than the size of the second electrode portion 122 along the second direction. The second direction is perpendicular to the first direction X and the thickness direction of the substrate 11. In FIG. 7, the second direction is a direction perpendicular to the paper surface.

As such, it is equivalent to making a width of the second shielding portion 16 not smaller than the width of the second electrode portion 122. As such, a shielding area of the second shielding portion 16 can be made larger, which can maximally alleviate the problem of the bright line in the gap.

In one example, the size of the second shielding portion 16 along the second direction is greater than the size of the second electrode portion 122 along the second direction. In another example, the size of the second shielding portion 16 along the second direction is equal to the size of the second electrode portion 122 along the second direction.

In an embodiment, the size of the second shielding portion 16 along the second direction is not smaller than the size of the first electrode portion 121 along the second direction.

As such, it is equivalent to making the width of the second shielding portion 16 not smaller than the width of the first electrode portion 121. As such, the shielding area of the second shielding portion 16 can be larger, which can maximally alleviate the problem of bright line in the gap.

In one example, the size of the second shielding portion 16 along the second direction is greater than the size of the first electrode portion 121 along the second direction. In another example, the size of the second shielding portion 16 along the second direction is equal to the size of the first electrode portion 121 along the second direction.

In an embodiment, as shown in FIG. 12, the touch panel 10 includes an anode metal layer 110 provided between the touch structure layer 12 and the substrate 11. The area between the orthographic projection of the first electrode portion 121 on the substrate 11 and the orthographic projection of the second electrode portion 122 on the substrate 11 is a spacing region, and at least a part of the spacing region is located outside of an orthographic projection of the anode metal layer 110 on the substrate 11.

Through research, the inventor found that the reflectivity of the anode metal layer 110 is higher than the reflectivity of the metal in the touch structure layer 12. Under strong light, the light reflected by the anode metal layer 110 is emitted from the gap S, resulting in the problem of bright line in the gap. The above configuration is equivalent to making a part of the metal of the anode metal layer 110 not overlap with the gap S, which is conducive to improving the problem of bright line in the gap caused by the anode metal layer 110.

It is understood that, as shown in FIG. 12, the touch panel 10 may further include a driving structure layer 19, a light-emitting layer 111, and a cathode metal layer 112. The anode metal layer 110 is provided on the driving structure layer 19, the light-emitting layer 111 is provided on one side of the anode metal layer 110 away from the driving structure layer 19, the cathode metal layer 112 is provided on one side of the light-emitting layer 111 away from the driving structure layer 19, and the touch structure layer 12 is provided on one side of the cathode metal layer 112 away from the driving structure layer 19. It can be understood that an encapsulation layer (not shown in the figures) may be provided between the touch structure layer 12 and the cathode metal layer 112.

In a second aspect, as shown in FIG. 13, an embodiment of the present disclosure provides a display apparatus 1 including a touch panel in any one of the embodiments in the first aspect.

The display apparatus 1 can be a notebook computer, a mobile phone, a wireless apparatus, a personal digital assistant (PDA), a handheld or portable computer, a global positioning system (GPS) receiver/navigator, a camera, an MP4 video player, a camcorder, a game console, a watch, a clock, a calculator, a television monitor, a flat panel display, a computer monitor, a car display (e.g., an odometer display, etc.), a navigator, a cockpit controller and/or display, a display of a camera view (e.g., a display of a rearview camera in a vehicle), an electronic photo, an electronic billboard or sign, a projector, etc.

The technical features in the above embodiments can be combined in any way. To make the description concise, not all possible combinations of the technical features in the above embodiments are described. However, the combinations of these technical features, unless in contradiction, should be regarded as falling within the scope of the specification.

The above embodiments only represent several implementations of the present disclosure, which are described in a more specific and detailed manner, but cannot be construed as a limitation of the patent scope of the disclosure as a result. It should be pointed out that, for a person of ordinary skill in the art, several variations and improvements can be made without departing from the concept of the present disclosure, and these all fall within the protection scope of the present disclosure. Therefore, the protection scope of the present disclosure shall be subject to the appended claims.

What is claimed is:

1. A touch panel, comprising:
a substrate;
a touch structure layer provided on one side of the substrate and comprising a first electrode portion and a second electrode portion, wherein the first electrode portion and the second electrode portion are provided at intervals along a first direction; and
a first shielding portion connected to the first electrode portion, wherein a distance between the first shielding portion and the substrate is not equal to a distance between the first electrode portion and the substrate,
wherein at least a part of an orthographic projection of the first shielding portion on the substrate is located between an orthographic projection of the first electrode portion on the substrate and an orthographic projection of the second electrode portion on the substrate, and the first direction is perpendicular to a thickness direction of the substrate.

2. The touch panel according to claim 1, wherein,
the first shielding portion is located on one side of the first electrode portion close to the substrate; and
the touch panel further comprises a first insulating layer located between the first electrode portion and the substrate and between the second electrode portion and the substrate, wherein the first insulating layer comprises a first receiving groove, and the first shielding portion is located in the first receiving groove.

3. The touch panel according to claim 1, wherein,
an included angle between an end surface of the first shielding portion close to an end of the first electrode portion along the first direction and a plane of the substrate is an acute angle.

4. The touch panel according to claim 3, wherein,
an included angle between an end surface of the first shielding portion away from the end of the first electrode portion along the first direction and the plane of the substrate is an acute angle; or
an included angle between an end surface of the first shielding portion away from the end of the first electrode portion along the first direction and the plane of the substrate is an obtuse angle.

5. The touch panel according to claim 1, wherein,
the distance between the first electrode portion and the substrate is equal to a distance between the second electrode portion and the substrate; and
the orthographic projection of the first shielding portion on the substrate is spaced apart from the orthographic projection of the second electrode portion on the substrate.

6. The touch panel according to claim 1, wherein,
the distance between the first electrode portion and the substrate is not equal to a distance between the second electrode portion and the substrate; and
the orthographic projection of the first shielding portion on the substrate covers an area between the orthographic projection of the first electrode portion on the substrate and the orthographic projection of the second electrode portion on the substrate.

7. The touch panel according to claim 6, further comprising a second insulating layer, wherein the second insulating layer is located on one side of the first electrode portion and one side of the first shielding portion away from the substrate, and the second insulating layer is located on one side of the second electrode portion close to the substrate.

8. The touch panel according to claim 1, wherein,
a size of the first shielding portion along a second direction is not less than a size of the first electrode portion along the second direction; and/or
a size of the first shielding portion along a second direction is not less than a size of the second electrode portion along the second direction;
the second direction is perpendicular to the first direction and the thickness direction of the substrate.

9. The touch panel according to claim 1, further comprising a second shielding portion, wherein the second shielding portion is connected to the second electrode portion, and a distance between the second shielding portion and the substrate is not equal to a distance between the second electrode portion and the substrate;
wherein at least a part of an orthographic projection of the second shielding portion on the substrate is located between the orthographic projection of the first electrode portion on the substrate and the orthographic projection of the second electrode portion on the substrate.

10. The touch panel according to claim 9, wherein,
the second shielding portion is provided on one side of the second electrode portion away from the substrate; and
the touch panel further comprises a third insulating layer, wherein the third insulating layer is located on one side of the first electrode portion and one side of the second electrode portion away from the substrate, the third insulating layer comprises a second receiving groove, and the second shielding portion is provided in the second receiving groove.

11. The touch panel according to claim 9, wherein,
an included angle between an end surface of the second shielding portion close to an end of the second electrode portion along the first direction and a plane of the substrate is an acute angle; and
an included angle between an end surface of the second shielding portion away from the end of the second electrode portion along the first direction and the plane of the substrate is an acute angle.

12. The touch panel according to claim 9, wherein,
a size of the second shielding portion along a second direction is not less than a size of the second electrode portion along the second direction; and/or
a size of the second shielding portion along a second direction is not less than a size of the first electrode portion along the second direction;
the second direction is perpendicular to the first direction and the thickness direction of the substrate.

13. The touch panel according to claim 9, wherein,
the orthographic projection of the first shielding portion on the substrate overlaps or contacts the orthographic projection of the second shielding portion on the substrate.

14. The touch panel according to claim 1, further comprising an optical film layer, wherein the optical film layer is located on one side of the first electrode portion and one side of the second electrode portion away from the substrate; and
a gap is formed between the first electrode portion and the second electrode portion, one side of the optical film layer away from the substrate comprises a groove, and along the thickness direction of the substrate, the groove and the gap overlap.

15. The touch panel according to claim 14, wherein,
the groove has a first side wall and a second side wall provided opposite to each other along the first direction, wherein the first side wall is located on one side of the second side wall close to the first electrode portion; and
an included angle is formed between a plane of the first side wall and a plane of the substrate, and an included angle is formed between a plane of the second side wall and the plane of the substrate.

16. The touch panel according to claim 15, wherein,
the included angle α₁ between the plane of the first side wall and the plane of the substrate satisfies a relationship: 30°≤α₁<90°; and/or
the included angle α₂ between the plane of the second side wall and the plane of the substrate satisfies a relationship: 30°<α₂<90°.

17. The touch panel according to claim 14, wherein,
the groove penetrates partial structure of the optical film layer along the thickness direction of the substrate.

18. The touch panel according to claim 1, wherein,
one of the first electrode portion and the second electrode portion is a touch driving electrode, and the other is a touch sensing electrode; or
one of the first electrode portion and the second electrode portion is a touch driving electrode, and the other is a dummy electrode; or
one of the first electrode portion and the second electrode portion is a touch sensing electrode, and the other is a dummy electrode.

19. The touch panel according to claim 1, further comprising an anode metal layer provided between the touch structure layer and the substrate; and
an area between the orthographic projection of the first electrode portion on the substrate and the orthographic projection of the second electrode portion on the substrate is a spacing area, and at least a part of the spacing area is located outside an orthographic projection of the anode metal layer on the substrate.

20. A display apparatus, comprising a touch panel, wherein the touch panel comprises:
a substrate;
a touch structure layer provided on one side of the substrate and comprising a first electrode portion and a second electrode portion, wherein the first electrode portion and the second electrode portion are provided at intervals along a first direction; and
a first shielding portion connected to the first electrode portion, wherein a distance between the first shielding portion and the substrate is not equal to a distance between the first electrode portion and the substrate,
wherein at least a part of an orthographic projection of the first shielding portion on the substrate is located between an orthographic projection of the first electrode portion on the substrate and an orthographic projection of the second electrode portion on the substrate, and the first direction is perpendicular to a thickness direction of the substrate.
